(19) United States
(12) Patent Application Publication
(10) Pub. No.: US 2019/0390326 A1
(43) Pub. Date: Dec. 26, 2019

(54) SUBSTRATE STAGE AND FILM FORMING APPARATUS

(71) Applicant: Tokyo Electron Limited, Tokyo (JP)

(72) Inventors: Junichi Takei, Yamanashi (JP); Naoyuki Suzuki, Tokyo (JP); Hiroshi Sone, Tokyo (JP); Shinji Orimoto, Yamanashi (JP)

(21) Appl. No.: 16/442,721

(22) Filed: Jun. 17, 2019

(30) Foreign Application Priority Data
Jun. 22, 2018 (JP) 2018-119138

(51) Int. Cl. C23C 14/50; C23C 14/34

(52) U.S. Cl. CPC C23C 14/505; C23C 14/34

(57) ABSTRACT

A substrate stage includes: a shaft rotatably disposed with respect to a bottom surface of a processing container; a base provided on the shaft; and a horizontal mover attached to the base and configured to move a substrate in the processing container in a horizontal direction with respect to the bottom surface.

### CROSS-REFERENCE TO RELATED APPLICATIONS

This application is based on and claims priority from Japanese Patent Application No. 2018-119138 filed on Jun. 22, 2018 with the Japan Patent Office, the disclosure of which is incorporated herein in its entirety by reference.

### TECHNICAL FIELD

The present disclosure relates to a substrate stage and a film forming apparatus.

### BACKGROUND

A sputtering apparatus is known to perform a film forming process by making sputtered particles to be obliquely incident on a substrate (see, e.g., Japanese Patent Laid-Open Publication No. 2015-067856). In this sputtering apparatus, the film forming process is performed while moving a substrate holder on which a substrate is mounted in the horizontal direction.

### SUMMARY

A substrate stage according to an aspect of the present disclosure includes: a shaft rotatably disposed with respect to a bottom surface of a processing container; a base provided on the shaft; and a horizontal mover attached to the base and configured to move a substrate in the processing container in a horizontal direction with respect to the bottom surface.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic cross-sectional view illustrating an exemplary configuration of a film forming apparatus.

FIG. 2 is a schematic cross-sectional view illustrating a stage of a first embodiment.

FIG. 3 is a schematic cross-sectional view illustrating a stage of a second embodiment.

### DETAILED DESCRIPTION

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

(Film Forming Apparatus)

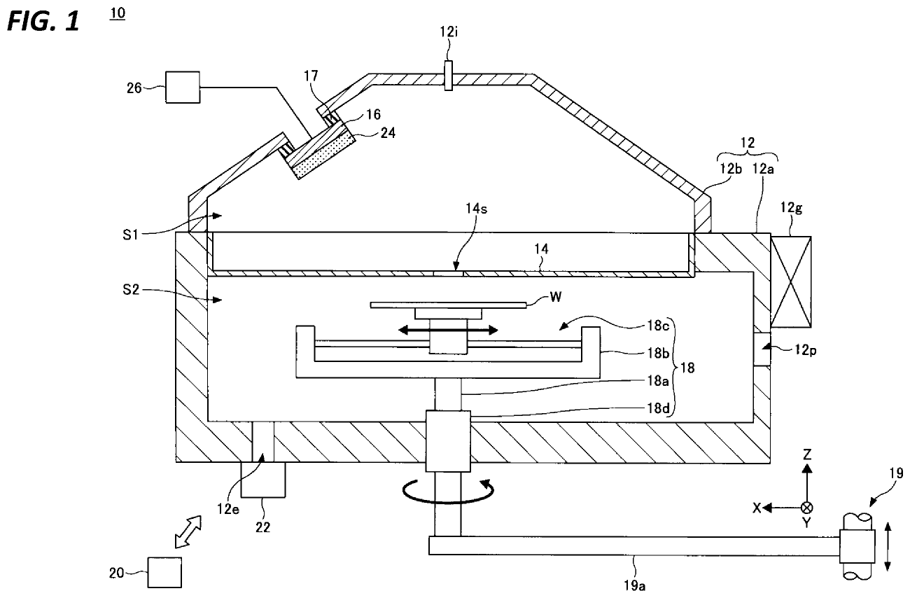

An exemplary configuration of a film forming apparatus will be described. FIG. 1 is a schematic cross-sectional view illustrating an exemplary configuration of a film forming apparatus.

A film forming apparatus 10 is a sputtering apparatus that forms a film on a substrate W by sputtering. The film forming apparatus 10 includes a processing container 12, a slit plate 14, a holder 16, a stage 18, and a controller 20.

The processing container 12 includes a main body 12a and a cover 12b. The main body 12a has, for example, a substantially cylindrical shape. The upper end portion of the main body 12a is opened. The cover 12b is provided on the upper end of the main body 12a, and closes an opening at the upper end of the main body 12a.

An exhaust port 12e is formed at the bottom of the processing container 12. An exhaust device 22 is connected to the exhaust port 12e. The exhaust device includes, for example, a pressure controller and a depressurizing pump. The depressurizing pump may be, for example, a dry pump or a turbo molecular pump.

An opening 12p is formed at a side wall of the processing container 12. The carrying of the substrate W into the processing container 12 and the carrying of the substrate W out from the processing container 12 are performed through the opening 12p. The opening 12p is opened and closed by a gate valve 12g.

A port 12i is provided at the processing container 12 to introduce a gas into the processing container 12. Therefore, a gas (e.g., inert gas) from a gas supply is introduced into the processing container 12 through the port 12i.

The slit plate 14 is provided inside the processing container 12. The slit plate 14 is a substantially plate-shaped member. The slit plate 14 extends horizontally at an intermediate position in the height direction of the processing container 12. An edge of the slit plate 14 is held by the processing container 12. The slit plate 14 divides the inside of the processing container 12 into a first space S1 and a second space S2. The first space S1 is a part of the space in the processing container 12, which is located above the slit plate 14. The second space S2 is another part of the space in the processing container 12, which is located below the slit plate 14.

A slit 14s is formed at the slit plate 14. The slit 14s penetrates the slit plate 14 in the plate thickness direction (Z direction in FIG. 1). The slit plate 14 may be, for example, a single component, or a combination of a plurality of components. At the time of film formation, the substrate W is moved in an X direction below the slit 14s. The X direction is one horizontal direction. The slit 14s extends to be elongated along a Y direction which is another horizontal direction, and has, for example, a substantially rectangular planar shape. The Y direction is a longitudinal direction of the slit 14s, and is a direction that is perpendicular to the X direction. The center of the slit 14s in the Y direction substantially coincides with the center of the substrate W in the Y direction at the time of film formation. A width of the slit 14s in the Y direction is longer than a width (the maximum width) of the substrate W in the Y direction at the time of film formation. Meanwhile, a width of the slit 14s in the X direction is shorter than a width (the maximum width) of the substrate W in the X direction at the time of film formation.

A holder 16 is provided above the slit plate 14. The holder 16 is made of a conductive material. The holder 16 is attached to the cover 12b via an insulating member 17. The holder 16 holds a target 24 disposed in the first space S1. The holder 16 holds the target 24 such that, for example, the target 24 is positioned obliquely above the slit 14s. Meanwhile, the holder 16 may hold the target 24 such that the target 24 is positioned immediately above the slit 14s. The target 24 has, for example, a substantially rectangular planar shape. A width of the target 24 in the Y direction is larger than, for example, a width (the maximum width) of the substrate W in the Y direction at the time of film formation.

A power supply 26 is connected to the holder 16. When the target 24 is a metal material, the power supply 26 may be a DC power supply. The power supply 26 may be a radio-frequency power supply when the target 24 is a dielectric or an insulator, and is connected to the holder 16 via a matching unit.

A stage 18 is an example of the substrate stage, and supports the substrate W in the processing container 12. The stage 18 is movable in the horizontal direction (X direction in FIG. 1) and the vertical direction (Z direction in FIG. 1) with respect to the bottom surface of the processing container 12, and is rotatable in the horizontal direction about the vertical direction serving as the rotation axis. The horizontal direction with respect to the bottom surface of the processing container 12 includes a direction horizontal to the bottom surface of the processing container 12, a direction that orthogonally intersects the rotation axis, and a direction within ±3° with respect to these directions. The stage 18 includes a shaft 18a, a base 18b, and a horizontal movement mechanism 18c. The shaft 18a is provided at the center of the bottom surface of the main body 12a so as to penetrate the main body 12a through a magnetic fluid seal portion 18d. A lower portion of the shaft 18a is rotatably supported by an arm 19a of a lift mechanism 19. The base 18b is provided on the upper end of the shaft 18a, and the horizontal movement mechanism 18c that supports the substrate W and also moves the substrate W in the horizontal direction (X direction in FIG. 1) is provided on the base 18b. Therefore, by moving the lift mechanism 19 up and down, the shaft 18a, the base 18b, and the horizontal movement mechanism 18c are integrally moved up and down (moved in the vertical direction), and by rotating the shaft 18a, the base 18b and the horizontal movement mechanism 18c are integrally rotated. For example, when performing the film forming on the substrate W, the shaft 18a, the base 18b, and the horizontal movement mechanism 18c are raised by the lift mechanism 19 and the upper surface of the substrate W is brought close to the slit plate 14, and then, the substrate W is moved along the horizontal direction (X direction in FIG. 1) by the horizontal movement mechanism 18c.

The controller 20 controls an operation of each component of the film forming apparatus 10, for example, the gate valve 12g, the horizontal movement mechanism 18c, the lift mechanism 19, the exhaust device 22, and the power supply 26. The controller 20 includes a central processing unit (CPU), a read only memory (ROM), and a random access memory (RAM). The CPU executes a desired processing according to a recipe stored in a memory area such as the RAM. Control information of the apparatus with respect to the process condition is set in the recipe. The control information may be, for example, gas flow rate, pressure, temperature, and process time. A program used by the recipe and the controller 20 may be stored in, for example, a hard disk or a semiconductor memory. The recipe or the like may be set at a predetermined position and read out while being stored in a storage medium readable by a portable computer such as a CD-ROM or a DVD.

(Stage)

### First Embodiment

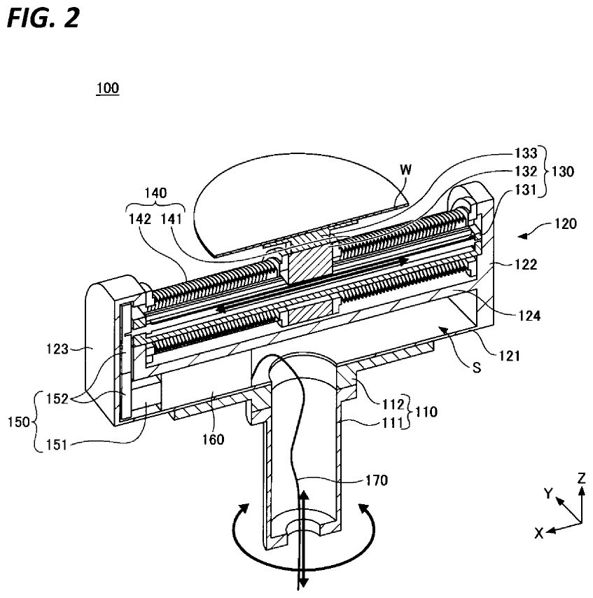

A stage of a first embodiment will be described. FIG. 2 is a schematic cross-sectional view illustrating the stage of the first embodiment.

As illustrated in FIG. 2, a stage 100 includes a shaft 110, a base 120, a horizontal movement mechanism 130, bellows 140, a power transmission mechanism 150, and a driving source 160.

The shaft 110 is provided at the center of the bottom surface of the processing container 12 so as to penetrate the processing container 12 through the magnetic fluid seal portion 18d. A lower portion of the shaft 110 is rotatably supported by the arm 19a of the lift mechanism 19. The shaft 110 is, for example, a bonded member of a cylindrical member 111 and an annular member 112, and the lower end of the annular member 112 is supported by the arm 19a of the lift mechanism 19. Meanwhile, the shaft 110 may be, for example, an integrally formed member.

The base 120 is provided on the upper end of the shaft 110. The base 120 functions as a case that accommodates the power transmission mechanism 150 and the driving source 160. The base 120 includes, for example, a bottom 121, a right portion 122, a left portion 123, a front portion (not illustrated), a back portion (not illustrated), and a ceiling 124. The bottom 121 is fixed on the shaft 110. The bottom 121 has, for example, a rectangular shape in which a longitudinal direction is one horizontal direction (X direction in FIG. 2) and a width direction is another horizontal direction (Y direction in FIG. 2). The right portion 122 and the left portion 123 are formed to respectively extend upward (Z direction in FIG. 2) from one end and another end of the bottom 121 in the longitudinal direction. The front portion and the back portion are formed to respectively extend upward from one end and another end of the bottom 121 in the width direction. The ceiling 124 is connected to the right portion 122, the left portion 123, the front portion, and the back portion to form a space S between the bottom 121, the right portion 122, the left portion 123, the front portion, and the back portion.

The horizontal movement mechanism 130 is attached to the base 120. The horizontal movement mechanism 130 supports the substrate W and moves the substrate W in the longitudinal direction of the base 120 by the power of the driving source 160. The horizontal movement mechanism 130 includes a guide 131, a moving portion 132, and a support 133. The guide 131 is fixed to the right portion 122 of the base 120 at its one end, and fixed to the left portion 123 of the base 120 at its another end. The moving portion 132 is attached so as to be movable along the longitudinal direction of the guide 131. The support 133 is connected to the upper end of the moving portion 132, and is moved integrally with the moving portion 132. The substrate W is disposed on the upper surface of the support 133. The moving portion 132 and the support 133 may be integrally formed. The horizontal movement mechanism 130 may be, for example, a linear guide, a ball spline, or a ball screw.

The bellows 140 include first bellows 141 and second bellows 142. The first bellows 141 is provided to cover the guide 131, and its one end is connected to the right portion 122 of the base 120 and its another end is connected to the moving portion 132. The second bellows 142 is provided to cover the guide 131, and its one end is connected to the left portion 123 of the base 120 and its another end is connected to the moving portion 132. As a result, it is possible to isolate the atmosphere provided with the guide 131 from the atmosphere in the processing container 12. Therefore, it is possible to maintain the atmosphere in the processing container 12 in vacuum and to perform the film forming on the substrate W, while, for example, the atmosphere provided with the guide 131 is maintained at atmospheric pressure and the moving portion 132 is moved along the longitudinal direction of the guide 131.

The power transmission mechanism 150 is a mechanism that transmits the power of the driving source 160 to the horizontal movement mechanism 130, and is provided in the space S of the base 120. The power transmission mechanism 150 is connected to a reduction gear 151 connected to an output shaft of the driving source 160, and a plurality of gears 152 connected to an output shaft of the reduction gear 151 and connected to an input shaft of the horizontal movement mechanism 130.

The driving source 160 is provided inside the processing container 12. The driving source 160 is provided, for example, in the space S of the base 120 of the stage 100 provided inside the processing container 12. The driving source 160 generates a driving force for moving the moving portion 132 of the horizontal movement mechanism 130 via the power transmission mechanism 150. The driving source 160 is, for example, a motor. Electric power for operating the driving source 160 is supplied by, for example, a cable 170 provided inside the shaft 110 and in the space S of the base 120.

By the way, as a method of moving the substrate in the horizontal direction in the processing container, for example, a method in which a conveyance arm such as an articulated arm is used, or a method in which a stage having a rotation mechanism is moved in the processing container may be used.

In the method in which the conveyance arm is used, since the substrate W is in a cantilever state on the conveyance arm, the influence of bending or inertia may occur. Further, when changing the direction of the substrate W or performing fine adjustment, it is necessary to convey the substrate to an aligner or an orienter provided separately from the processing container, and thus, the throughput is reduced.

In the method in which the stage having the rotation mechanism is moved in the processing container, since the weight of the stage is large, the influence of vibration or inertia may occur when the stage is moved.

Meanwhile, the stage 100 of the first embodiment includes the shaft 110 disposed rotatably with respect to the bottom surface of the processing container 12, the base 120 provided on the shaft 110, and the horizontal movement mechanism 130 that is attached to the base 120 and moves the substrate W in the horizontal direction. As a result, the load resistance of the stage 100 is improved, and thus, it is possible to move the substrate W in the horizontal direction in the processing container 12 without being affected by bending, vibration, and inertia. Therefore, the positional accuracy of the substrate W may be enhanced.

Further, the stage 100 of the first embodiment includes the shaft 110 disposed rotatably with respect to the bottom surface of the processing container 12. Therefore, by applying the stage 100 to a multi-target sputtering apparatus, it is possible to perform the film forming with the direction of the substrate W aligned with the desired target. Further, since the moving direction of the substrate W with respect to the slit may be implemented by merely rotating the base 120, the incident angle of sputtered particles to the substrate W may be easily adjusted or finely adjusted, and the film forming may be performed under proper conditions.

Further, the stage 100 of the first embodiment includes a lift mechanism that integrally moves the shaft 110, the base 120, and the horizontal movement mechanism 130 up and down. Therefore, by applying the stage 100 to a sputtering apparatus that performs film forming by making sputtered particles being incident on the substrate W in an inclined direction, it is possible to perform the film forming at a desired angle with respect to the substrate W.

### Second Embodiment

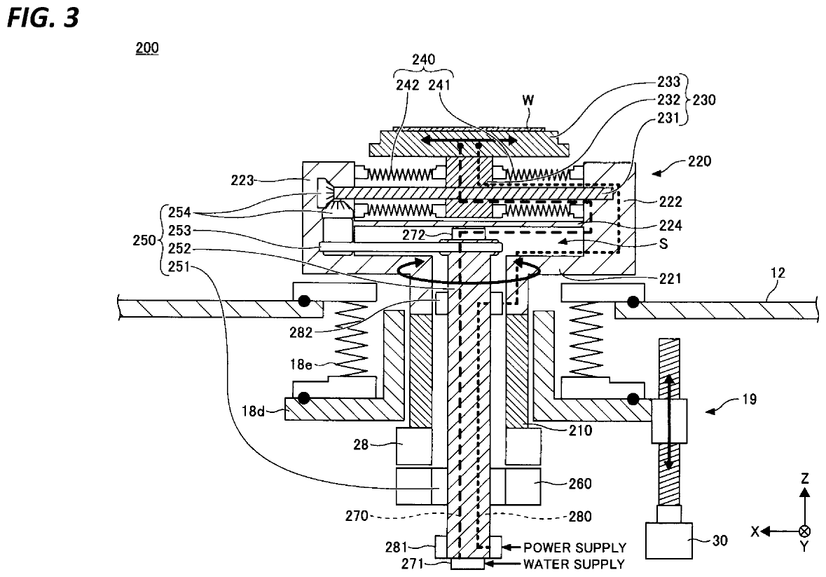

A stage of a second embodiment will be described. In the stage of the second embodiment, a driving source that operates a horizontal movement mechanism is provided outside a processing container. FIG. 3 is a schematic cross-sectional view illustrating the stage of the second embodiment.

As illustrated in FIG. 3, a stage 200 includes a shaft 210, a base 220, a horizontal movement mechanism 230, bellows 240, a power transmission mechanism 250, and a driving source 260.

The shaft 210 is provided at the center of the bottom surface of the processing container 12 so as to penetrate the processing container 12 through the magnetic fluid seal portion 18d. A driving source 28 such as a direct drive motor is provided below the shaft 210, and the shaft 210 is rotated by the power of the driving source 28. The shaft 210 is connected to the lift mechanism 19 such as a ball spline or a ball screw. The shaft 210 is moved up and down with respect to the bottom surface of the processing container 12 by moving the lift mechanism 19 by a driving source 30 such as a servo motor. The magnetic fluid seal portion 18d is covered with bellows 18e.

The base 220 is provided on the upper end of the shaft 210. The base 220 functions as a case that accommodates the power transmission mechanism 250. The base 220 includes, for example, a bottom 221, a right portion 222, a left portion 223, a front portion (not illustrated), a back portion (not illustrated), and a ceiling 224. The bottom 221 is fixed on the shaft 210. The bottom 221 has, for example, a rectangular shape in which a longitudinal direction is one horizontal direction (X direction in FIG. 3) and a width direction is another horizontal direction (Y direction in FIG. 3). The right portion 222 and the left portion 223 are formed to respectively extend upward (Z direction in FIG. 3) from one end and another end of the bottom 221 in the longitudinal direction. The front portion and the back portion are formed to respectively extend upward from one end and another end of the bottom 221 in the width direction. The ceiling 224 is connected to the right portion 222, the left portion 223, the front portion, and the back portion to form a space S between the bottom 221, the right portion 222, the left portion 223, the front portion, and the back portion.

The horizontal movement mechanism 230 is attached to the base 220. The horizontal movement mechanism 230 supports the substrate W, and moves the substrate W in the longitudinal direction of the base 220 by the power of the driving source 260. The horizontal movement mechanism 230 includes a guide 231, a moving portion 232, and a support 233. The guide 231 is fixed to the right portion 222 of the base 220 at its one end, and fixed to the left portion 223 of the base 220 at its another end. The moving portion 232 is attached so as to be movable along the longitudinal direction of the guide 231. The support 233 is connected to the upper end of the moving portion 232, and is moved integrally with the moving portion 232. The substrate W is disposed on the upper surface of the support 233. The horizontal movement mechanism 230 may be, for example, a linear guide, a ball spline, or a ball screw.

The bellows 240 include first bellows 241 and second bellows 242. The first bellows 241 is provided to cover the guide 231, and its one end is connected to the right portion 222 of the base 220 and its another end is connected to the moving portion 232. The second bellows 242 is provided to cover the guide 231, and its one end is connected to the left portion 223 of the base 220 and its another end is connected to the moving portion 232. As a result, it is possible to isolate the atmosphere provided with the guide 231 from the atmosphere in the processing container 12. Therefore, it is possible to maintain the atmosphere in the processing container 12 in vacuum and to perform the film forming on the substrate W, while, for example, the atmosphere provided with the guide 231 is maintained at atmospheric pressure and the moving portion 232 is moved along the longitudinal direction of the guide 231.

The power transmission mechanism 250 is a mechanism that transmits the power of the driving source 260 to the horizontal movement mechanism 230. The power transmission mechanism 250 includes, for example, a reduction gear 251, a rotary shaft 252, a belt 253, and a plurality of gears 254. The reduction gear 251 is connected to an output shaft of the driving source 260, and reduces the rotational speed of the power of the driving source 260 and outputs the power. The reduction gear 251 may be, for example, a Harmonic Drive (registered trademark). The rotary shaft 252 is provided inside the shaft 210 through the magnetic fluid seal portion 18d. The rotary shaft 252 is connected to an output shaft of the reduction gear 251, and is rotated according to the output of the reduction gear 251. The belt 253 is connected to an output shaft of the rotary shaft 252 at the upper end of the rotary shaft 252, and is rotated according to the rotation of the rotary shaft 252. The plurality of gears 254 are connected to the belt 253 and connected to an input shaft of the horizontal movement mechanism 230, and transmits the rotational power according to the rotation of the belt 253 to the horizontal movement mechanism 230.

The driving source 260 is provided outside the processing container 12. The driving source 260 is provided, for example, below the processing container 12. The driving source 260 generates a driving force for moving the moving portion 232 of the horizontal movement mechanism 230 via the power transmission mechanism 250. The driving source 260 is, for example, a direct drive motor.

The stage 200 may include a coolant channel 270 and a power wiring 280. The coolant channel 270 supplies coolant supplied from a coolant source to the support 233 via, for example, a rotary joint 271, the rotary shaft 252, and a rotary joint 272. The power wiring 280 supplies power supplied from a power source to a heating element (not illustrated) embedded in the support 233 via, for example, a slip ring 281, the rotary shaft 252, and a slip ring 282. It is possible to control the temperature of the substrate W disposed on the support 233 by controlling the flow rate of the coolant supplied to the support 233 via the coolant channel 270, and controlling the power supplied to the heating element via the power wiring 280.

The stage 200 of the second embodiment includes the shaft 210 disposed rotatably with respect to the bottom surface of the processing container 12, the base 220 provided on the shaft 210, and the horizontal movement mechanism 230 that is attached to the base 220 and moves the substrate W in the horizontal direction. As a result, the load resistance of the stage 200 is improved, and thus, it is possible to move the substrate W in the horizontal direction in the processing container 12 without being affected by bending, vibration, and inertia. Therefore, the positional accuracy of the substrate W may be enhanced.

Further, the stage 200 of the second embodiment includes the shaft 210 disposed rotatably with respect to the bottom surface of the processing container 12. Therefore, by applying the stage 200 to a multi-target sputtering apparatus, it is possible to perform the film forming with the direction of the substrate W aligned with the desired target. Further, since the moving direction of the substrate W with respect to the slit may be implemented by merely rotating the base 220, the incident angle of sputtered particles to the substrate W may be easily adjusted or finely adjusted, and the film forming may be performed under proper conditions.

Further, the stage 200 of the second embodiment includes a lift mechanism that integrally moves the shaft 210, the base 220, and the horizontal movement mechanism 230 up and down. Therefore, by applying the stage 200 to a sputtering apparatus that performs film forming by making sputtered particles being incident on the substrate W in an inclined direction, it is possible to perform the film forming at a desired angle with respect to the substrate W.

Further, in the stage 200 of the second embodiment, the driving source 260 is provided outside the processing container 12. As a result, even in a case where the film forming is performed by heating the substrate W at a high temperature, it is possible to suppress the driving source 260 from becoming a high temperature, so that the driving source 260 may be prevented from being damaged by heat.

In the above embodiment, descriptions have been made on the case where the stage 18 is applied to the sputtering apparatus which is an example of the film forming apparatus 10. However, the present disclosure is not limited thereto, and, for example, may be applied to a chemical vapor deposition (CVD) apparatus.

According to the present disclosure, it is possible to enhance positional accuracy of a substrate by improving the load resistance of a substrate stage.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate stage comprising:
a shaft rotatably disposed with respect to a bottom surface of a processing container;
a base provided on the shaft; and
a horizontal mover attached to the base and configured to move a substrate in the processing container in a horizontal direction with respect to the bottom surface.

2. The substrate stage according to claim 1, wherein the horizontal mover includes:
a guide fixed to the base at both ends thereof; and
a moving portion movable in a longitudinal direction of the guide with respect to the guide.

3. The substrate stage according to claim 2, further comprising:
a bellows connected to the base at one end thereof and connected to the moving portion at the other end thereof, and configured to cover the guide.

4. The substrate stage according to claim 3, further comprising:
a driving source provided inside the processing container and configured to operate the horizontal mover.

5. The substrate stage according to claim 3, further comprising:
a driving source provided outside the processing container and configured to operate the horizontal mover.

6. The substrate stage according to claim 5, further comprising:
a lift configured to move the horizontal mover in a vertical direction.

7. The substrate stage according to claim 1, further comprising:
a driving source provided inside the processing container and configured to operate the horizontal mover.

8. The substrate stage according to claim 1, further comprising:
a driving source provided outside the processing container and configured to operate the horizontal mover.

9. The substrate stage according to claim 1, further comprising:
a lift configured to move the horizontal mover in a vertical direction.

10. A film forming apparatus comprising:
a processing container; and
a substrate stage provided in the processing container,
wherein the substrate stage includes:
a shaft rotatably disposed with respect to a bottom surface of a processing container;
a base provided on the shaft; and
a horizontal mover attached to the base and configured to move a substrate in the processing container in a horizontal direction with respect to the bottom surface.

11. The film forming apparatus according to claim 10, further comprising:
a slit plate disposed above the substrate stage; and
a target disposed above the slit plate.
